(19) United States
(12) Patent Application Publication
(10) Pub. No.: US 2018/0261686 A1
(43) Pub. Date: Sep. 13, 2018

(54) TRANSISTOR SIDEWALL FORMATION PROCESS

(71) Applicant: Applied Materials, Inc., Santa Clara, CA (US)

(72) Inventors: Samkuei Lin, Cupertino, CA (US); Ajay Bhatnagar, Mountain View, CA (US); Nitin Ingle, San Jose, CA (US)

(73) Assignee: Applied Materials, Inc., Santa Clara, CA (US)

(21) Appl. No.: 15/918,528

(22) Filed: Mar. 12, 2018

Related U.S. Application Data
(60) Provisional application No. 62/470,713, filed on Mar. 13, 2017.

(51) Int. Cl. H01L 29/66; H01L 21/3065; H01L 21/768; H01L 29/786

(52) U.S. Cl. CPC H01L 29/66742; H01L 21/3065; H01L 29/78696; H01L 29/66545; H01L 21/76897

(57) ABSTRACT

Processing methods may be performed to form a sidewall spacer on a semiconductor substrate. The methods may include laterally etching a first silicon-containing material relative to a second silicon-containing material. The first silicon-containing material and the second silicon-containing material may be disposed vertically from one another. The first silicon-containing material may also be positioned vertically between two regions of the second silicon-containing material. The methods may also include forming a spacer within a recess defined by the lateral etching between the two regions of the second silicon-containing material. The methods may further include forming a contact material adjacent to and contacting both the second silicon-containing material and the spacer.

### CROSS REFERENCES TO RELATED APPLICATIONS

This application claims priority to U.S. Provisional Application No. 62/470,713, filed Mar. 13, 2017. The entire contents of that application are hereby incorporated by reference in their entirety for all purposes.

### TECHNICAL FIELD

The present technology relates to semiconductor systems, processes, and equipment. More specifically, the present technology relates to systems and methods for forming and etching material layers on a semiconductor device.

### BACKGROUND

Integrated circuits are made possible by processes which produce intricately patterned material layers on substrate surfaces. Producing patterned material on a substrate requires controlled methods for removal of exposed material. Chemical etching is used for a variety of purposes including transferring a pattern in photoresist into underlying layers, thinning layers, or thinning lateral dimensions of features already present on the surface. Often it is desirable to have an etch process that etches one material faster than another facilitating, for example, a pattern transfer process or individual material removal. Such an etch process is said to be selective to the first material. As a result of the diversity of materials, circuits, and processes, etch processes have been developed with a selectivity towards a variety of materials.

Etch processes may be termed wet or dry based on the materials used in the process. A wet HF etch preferentially removes silicon oxide over other dielectrics and materials. However, wet processes may have difficulty penetrating some constrained trenches and also may sometimes deform the remaining material. Dry etch processes may penetrate into intricate features and trenches, but may not provide acceptable top-to-bottom profiles. As device sizes continue to shrink in next-generation devices, selectivity may play a larger role when only a few nanometers of material are formed in a particular layer, especially when the material is critical in the transistor formation. Many different etch process selectivities have been developed between various materials, although standard selectivities may no longer be suitable at current and future device scale.

Thus, there is a need for improved systems and methods that can be used to produce high quality devices and structures. These and other needs are addressed by the present technology.

### SUMMARY

Processing methods may be performed to form a sidewall spacer on a semiconductor substrate. The methods may include laterally etching a first silicon-containing material relative to a second silicon-containing material. The first silicon-containing material and the second silicon-containing material may be disposed vertically from one another. The first silicon-containing material may also be positioned vertically between two regions of the second silicon-containing material. The methods may also include forming a spacer within a recess defined by the lateral etching between the two regions of the second silicon-containing material. The methods may further include forming a contact material adjacent to and contacting both the second silicon-containing material and the spacer.

In some embodiments the first silicon-containing material may be partially recessed from two sides of a gate formation, and the contact may be formed on each of the two sides of the gate formation. At least one region of the second silicon-containing material may include a silicon nanowire. In embodiments the first silicon-containing material and the second silicon-containing material may be selected from the group consisting of silicon, silicon germanium, and silicon phosphide. The spacer may be or include silicon nitride, silicon carbide, or silicon oxycarbide. The methods may also include laterally etching the second silicon-containing material prior to forming the contact material. The contact material may be formed within a recess defined by the lateral etching of the second silicon-containing material. The first silicon-containing material and the second silicon containing material may be positioned between a dummy gate material and a semiconductor substrate. The first silicon-containing material may be etched laterally less than 10 nm. In some embodiments, the first silicon-containing material may include silicon germanium, and the contact material may include silicon phosphide, such as in an N-MOS structure. In some embodiments, the first silicon-containing material may include silicon, and the contact material may include silicon germanium, such as in a P-MOS structure.

The present technology also encompasses semiconductor structures. The structures may include a substrate, and may include a first silicon-containing material overlying the substrate. The structures may include a second silicon-containing material overlying the first silicon-containing material. The structures may include a recess defined on each of two opposite sides of the first silicon-containing material. The recess may be defined at least partially from above by the second silicon-containing material. The structures may include a spacer positioned within each recess adjacent the first silicon-containing material. The structures may also include a dummy gate material overlying the second silicon-containing material.

In embodiments, the dummy gate material may include polysilicon. The structures may also include a contact material adjacent the second silicon-containing material and the spacer. The first silicon-containing material may include silicon germanium, and the contact material may include silicon phosphide. The first silicon-containing material may include silicon, and the contact material may include silicon germanium.

The present technology also includes methods of forming semiconductor structures. The methods may include partially etching a first silicon-containing material relative to a second silicon-containing material. The first silicon-containing material and the second silicon-containing material may be disposed vertically from one another, and the partial etching may be performed laterally. The methods may include forming a spacer within a recess defined by the lateral etching and at least partially defined by the second silicon-containing material. The methods may include anisotropically etching the spacer material and the second silicon-containing material vertically towards a substrate. The methods may include partially etching the second silicon-containing material laterally along the spacer. The methods may also include forming a contact material adjacent to and contacting both the second silicon-containing material and the spacer.

In embodiments the first silicon-containing material may include silicon germanium, and the contact material may include silicon phosphide. In embodiments the first silicon-containing material may include silicon, and the contact material may include silicon germanium. The first silicon-containing material and the second silicon containing material may be positioned below a dummy gate material on the substrate. The dummy gate may be or include polysilicon, and at least one of the first silicon-containing material and the second silicon-containing material may be or include a nanowire.

Such technology may provide numerous benefits over conventional systems and techniques. For example, by forming the spacer prior to dummy gate removal, the present technology may provide more precise formation and processing of the sidewall spacers. Additionally, the techniques may allow for reduced loss of contact material and improved uniformity of formation by allowing recess formation on both sides of a gate structure. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of an exemplary processing system according to embodiments of the present technology.

FIG. 2A shows a schematic cross-sectional view of an exemplary processing chamber according to embodiments of the present technology.

FIG. 2B shows a detailed view of an exemplary showerhead according to embodiments of the present technology.

FIG. 3 shows a bottom plan view of an exemplary showerhead according to embodiments of the present technology.

FIG. 4 shows selected operations in a method of forming a semiconductor structure according to embodiments of the present technology.

FIGS. 5A-5K illustrate schematic perspective views of substrate materials on which selected operations are being performed according to embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

The present technology includes systems and components for semiconductor processing of small pitch features. In traditional processing of transistor structures that may utilize nanowires or other features, a spacer is formed subsequent dummy gate removal and after the source/drain contacts have been formed. This processing flow can cause several issues with the devices being fabricated. By forming the contact on one side of the gate, the traditional flow is limited to forming a recess from the gate side and then laterally inserting the spacer from that same side. Additional etching and deposition operations are then required to form the rest of the structure. The more lateral deposition of the spacer material may cause issues with uniformity in formation in each layer and between layers if multiple levels are included, and precision of formation becomes more difficult to control as well.

The present technology overcomes these issues with several adjustments to the process for removal and formation. By utilizing particular equipment and techniques that may provide superior deposition and removal over traditional processes, the present technology may produce spacers in the N-MOS and/or P-MOS regions prior to dummy gate removal. By forming the spacers earlier in the process, the present technology can form the spacers prior to contact formation, which may allow the spacers to be formed on both sides of a gate structure. This may allow fewer overall operations to be performed, and may provide more uniform structures, which may be more reliable.

Although the remaining disclosure will routinely identify specific etching processes utilizing the disclosed technology, it will be readily understood that the systems and methods are equally applicable to deposition and cleaning processes as may occur in the described chambers. Accordingly, the technology should not be considered to be so limited as for use with etching processes alone. The disclosure will discuss one possible system and chamber that can be used with the present technology to perform certain of the removal operations before describing operations of an exemplary process sequence according to the present technology.

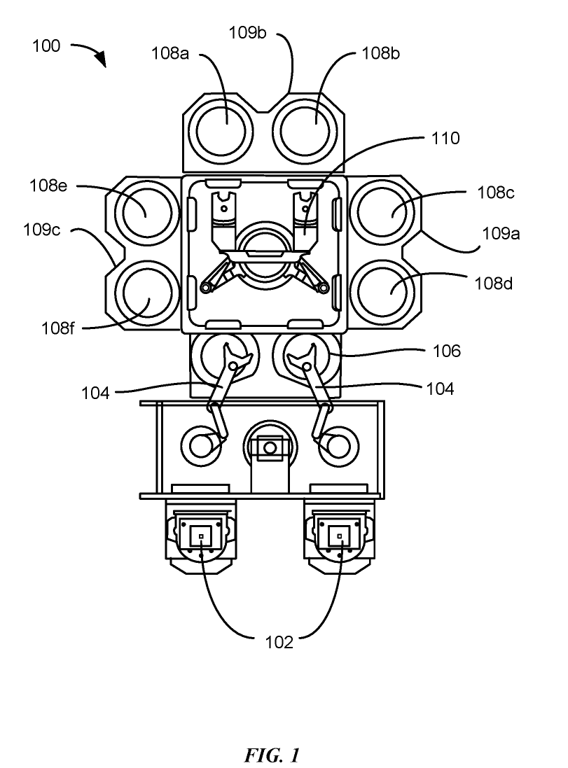

FIG. 1 shows a top plan view of one embodiment of a processing system 100 of deposition, etching, baking, and curing chambers according to embodiments. In the figure, a pair of front opening unified pods (FOUPs) 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f, can be outfitted to perform a number of substrate processing operations including the dry etch processes described herein in addition to cyclical layer deposition (CLD), atomic layer deposition (ALD), chemical vapor deposition (CVD), physical vapor deposition (PVD), etch, pre-clean, degas, orientation, and other substrate processes.

The substrate processing chambers 108a-f may include one or more system components for depositing, annealing, curing and/or etching a dielectric film on the substrate wafer. In one configuration, two pairs of the processing chambers, e.g., 108c-d and 108e-f, may be used to deposit dielectric material on the substrate, and the third pair of processing chambers, e.g., 108a-b, may be used to etch the deposited dielectric. In another configuration, all three pairs of chambers, e.g., 108a-f, may be configured to etch a dielectric film on the substrate. Any one or more of the processes described may be carried out in chamber(s) separated from the fabrication system shown in different embodiments. It will be appreciated that additional configurations of deposition, etching, annealing, and curing chambers for dielectric films are contemplated by system 100.

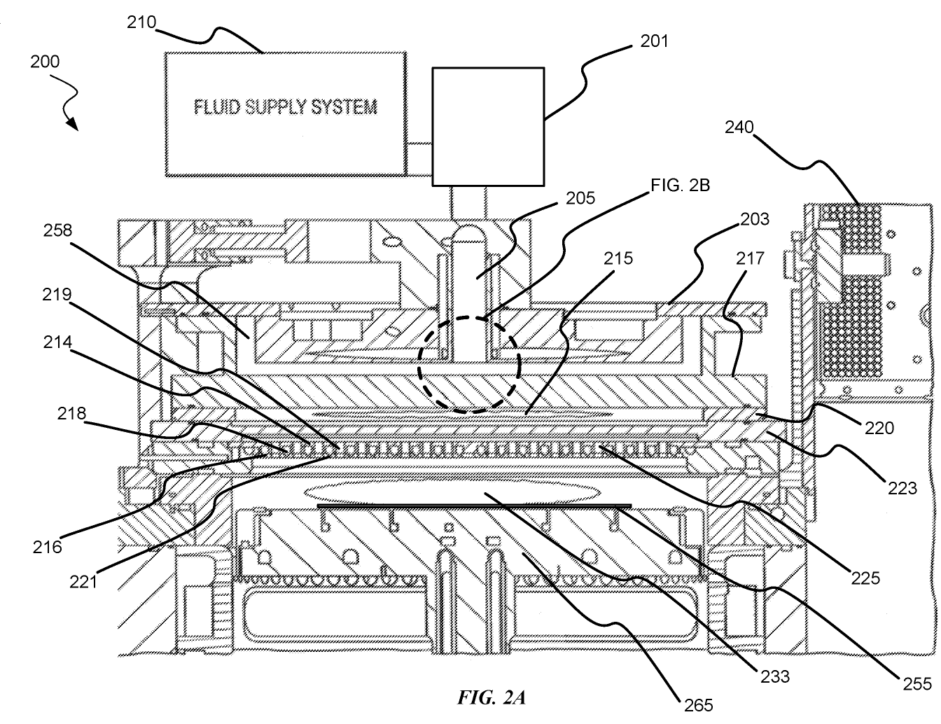

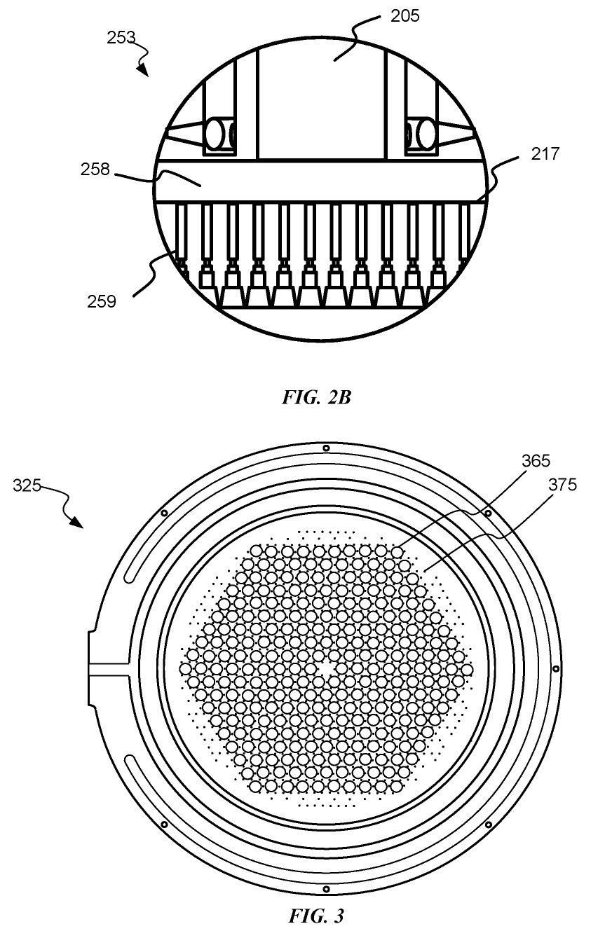

FIG. 2A shows a cross-sectional view of an exemplary process chamber system 200 with partitioned plasma generation regions within the processing chamber. During film etching, e.g., titanium nitride, tantalum nitride, tungsten, silicon, polysilicon, silicon oxide, silicon nitride, silicon oxynitride, silicon oxycarbide, etc., a process gas may be flowed into the first plasma region 215 through a gas inlet assembly 205. A remote plasma system (RPS) 201 may optionally be included in the system, and may process a first gas which then travels through gas inlet assembly 205. The inlet assembly 205 may include two or more distinct gas supply channels where the second channel (not shown) may bypass the RPS 201, if included.

A cooling plate 203, faceplate 217, ion suppressor 223, showerhead 225, and a substrate support 265, having a substrate 255 disposed thereon, are shown and may each be included according to embodiments. The pedestal 265 may have a heat exchange channel through which a heat exchange fluid flows to control the temperature of the substrate, which may be operated to heat and/or cool the substrate or wafer during processing operations. The wafer support platter of the pedestal 265, which may comprise aluminum, ceramic, or a combination thereof, may also be resistively heated in order to achieve relatively high temperatures, such as from up to or about 100° C. to above or about 1100° C., using an embedded resistive heater element.

The faceplate 217 may be pyramidal, conical, or of another similar structure with a narrow top portion expanding to a wide bottom portion. The faceplate 217 may additionally be flat as shown and include a plurality of through-channels used to distribute process gases. Plasma generating gases and/or plasma excited species, depending on use of the RPS 201, may pass through a plurality of holes, shown in FIG. 2B, in faceplate 217 for a more uniform delivery into the first plasma region 215.

Exemplary configurations may include having the gas inlet assembly 205 open into a gas supply region 258 partitioned from the first plasma region 215 by faceplate 217 so that the gases/species flow through the holes in the faceplate 217 into the first plasma region 215. Structural and operational features may be selected to prevent significant backflow of plasma from the first plasma region 215 back into the supply region 258, gas inlet assembly 205, and fluid supply system 210. The faceplate 217, or a conductive top portion of the chamber, and showerhead 225 are shown with an insulating ring 220 located between the features, which allows an AC potential to be applied to the faceplate 217 relative to showerhead 225 and/or ion suppressor 223. The insulating ring 220 may be positioned between the faceplate 217 and the showerhead 225 and/or ion suppressor 223 enabling a capacitively coupled plasma (CCP) to be formed in the first plasma region. A baffle (not shown) may additionally be located in the first plasma region 215, or otherwise coupled with gas inlet assembly 205, to affect the flow of fluid into the region through gas inlet assembly 205.

The ion suppressor 223 may comprise a plate or other geometry that defines a plurality of apertures throughout the structure that are configured to suppress the migration of ionically-charged species out of the first plasma region 215 while allowing uncharged neutral or radical species to pass through the ion suppressor 223 into an activated gas delivery region between the suppressor and the showerhead. In embodiments, the ion suppressor 223 may comprise a perforated plate with a variety of aperture configurations. These uncharged species may include highly reactive species that are transported with less reactive carrier gas through the apertures. As noted above, the migration of ionic species through the holes may be reduced, and in some instances completely suppressed. Controlling the amount of ionic species passing through the ion suppressor 223 may advantageously provide increased control over the gas mixture brought into contact with the underlying wafer substrate, which in turn may increase control of the deposition and/or etch characteristics of the gas mixture. For example, adjustments in the ion concentration of the gas mixture can significantly alter its etch selectivity, e.g., SiNx:SiOx etch ratios, Si:SiOx etch ratios, etc. In alternative embodiments in which deposition is performed, it can also shift the balance of conformal-to-flowable style depositions for dielectric materials.

The plurality of apertures in the ion suppressor 223 may be configured to control the passage of the activated gas, i.e., the ionic, radical, and/or neutral species, through the ion suppressor 223. For example, the aspect ratio of the holes, or the hole diameter to length, and/or the geometry of the holes may be controlled so that the flow of ionically-charged species in the activated gas passing through the ion suppressor 223 is reduced. The holes in the ion suppressor 223 may include a tapered portion that faces the plasma excitation region 215, and a cylindrical portion that faces the showerhead 225. The cylindrical portion may be shaped and dimensioned to control the flow of ionic species passing to the showerhead 225. An adjustable electrical bias may also be applied to the ion suppressor 223 as an additional means to control the flow of ionic species through the suppressor.

The ion suppressor 223 may function to reduce or eliminate the amount of ionically charged species traveling from the plasma generation region to the substrate. Uncharged neutral and radical species may still pass through the openings in the ion suppressor to react with the substrate. It should be noted that the complete elimination of ionically charged species in the reaction region surrounding the substrate may not be performed in embodiments. In certain instances, ionic species are intended to reach the substrate in order to perform the etch and/or deposition process. In these instances, the ion suppressor may help to control the concentration of ionic species in the reaction region at a level that assists the process.

Showerhead 225 in combination with ion suppressor 223 may allow a plasma present in first plasma region 215 to avoid directly exciting gases in substrate processing region 233, while still allowing excited species to travel from chamber plasma region 215 into substrate processing region 233. In this way, the chamber may be configured to prevent the plasma from contacting a substrate 255 being etched. This may advantageously protect a variety of intricate structures and films patterned on the substrate, which may be damaged, dislocated, or otherwise warped if directly contacted by a generated plasma. Additionally, when plasma is allowed to contact the substrate or approach the substrate level, the rate at which oxide species etch may increase. Accordingly, if an exposed region of material is oxide, this material may be further protected by maintaining the plasma remotely from the substrate.

The processing system may further include a power supply 240 electrically coupled with the processing chamber to provide electric power to the faceplate 217, ion suppressor 223, showerhead 225, and/or pedestal 265 to generate a plasma in the first plasma region 215 or processing region 233. The power supply may be configured to deliver an adjustable amount of power to the chamber depending on the process performed. Such a configuration may allow for a tunable plasma to be used in the processes being performed. Unlike a remote plasma unit, which is often presented with on or off functionality, a tunable plasma may be configured to deliver a specific amount of power to the plasma region 215. This in turn may allow development of particular plasma characteristics such that precursors may be dissociated in specific ways to enhance the etching profiles produced by these precursors.

A plasma may be ignited either in chamber plasma region 215 above showerhead 225 or substrate processing region 233 below showerhead 225. In embodiments, the plasma formed in substrate processing region 233 may be a DC biased plasma formed with the pedestal acting as an electrode. Plasma may be present in chamber plasma region 215 to produce the radical precursors from an inflow of, for example, a fluorine-containing precursor or other precursor. An AC voltage typically in the radio frequency (RF) range may be applied between the conductive top portion of the processing chamber, such as faceplate 217, and showerhead 225 and/or ion suppressor 223 to ignite a plasma in chamber plasma region 215 during deposition. An RF power supply may generate a high RF frequency of 13.56 MHz but may also generate other frequencies alone or in combination with the 13.56 MHz frequency.

FIG. 2B shows a detailed view 253 of the features affecting the processing gas distribution through faceplate 217. As shown in FIGS. 2A and 2B, faceplate 217, cooling plate 203, and gas inlet assembly 205 intersect to define a gas supply region 258 into which process gases may be delivered from gas inlet 205. The gases may fill the gas supply region 258 and flow to first plasma region 215 through apertures 259 in faceplate 217. The apertures 259 may be configured to direct flow in a substantially unidirectional manner such that process gases may flow into processing region 233, but may be partially or fully prevented from backflow into the gas supply region 258 after traversing the faceplate 217.

The gas distribution assemblies such as showerhead 225 for use in the processing chamber section 200 may be referred to as dual channel showerheads (DCSH) and are additionally detailed in the embodiments described in FIG. 3. The dual channel showerhead may provide for etching processes that allow for separation of etchants outside of the processing region 233 to provide limited interaction with chamber components and each other prior to being delivered into the processing region.

The showerhead 225 may comprise an upper plate 214 and a lower plate 216. The plates may be coupled with one another to define a volume 218 between the plates. The coupling of the plates may be so as to provide first fluid channels 219 through the upper and lower plates, and second fluid channels 221 through the lower plate 216. The formed channels may be configured to provide fluid access from the volume 218 through the lower plate 216 via second fluid channels 221 alone, and the first fluid channels 219 may be fluidly isolated from the volume 218 between the plates and the second fluid channels 221. The volume 218 may be fluidly accessible through a side of the gas distribution assembly 225.

FIG. 3 is a bottom view of a showerhead 325 for use with a processing chamber according to embodiments. Showerhead 325 may correspond with the showerhead 225 shown in FIG. 2A. Through-holes 365, which show a view of first fluid channels 219, may have a plurality of shapes and configurations in order to control and affect the flow of precursors through the showerhead 225. Small holes 375, which show a view of second fluid channels 221, may be distributed substantially evenly over the surface of the showerhead, even amongst the through-holes 365, and may help to provide more even mixing of the precursors as they exit the showerhead than other configurations.

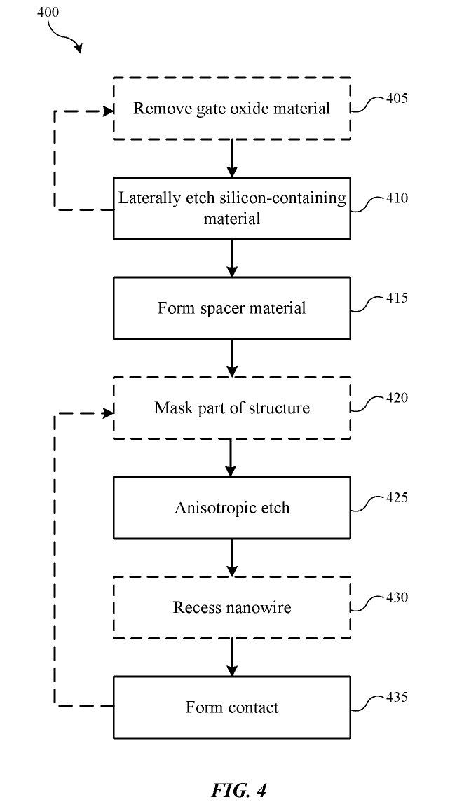

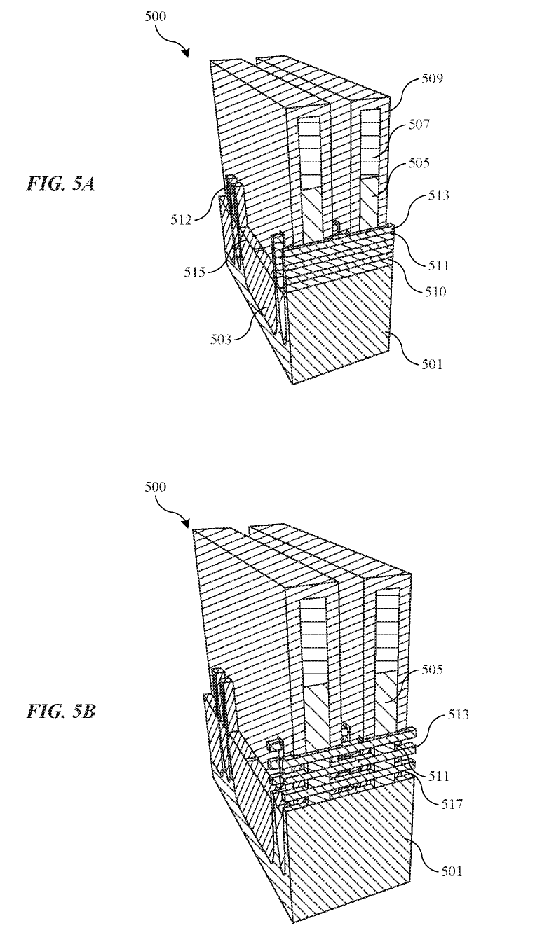

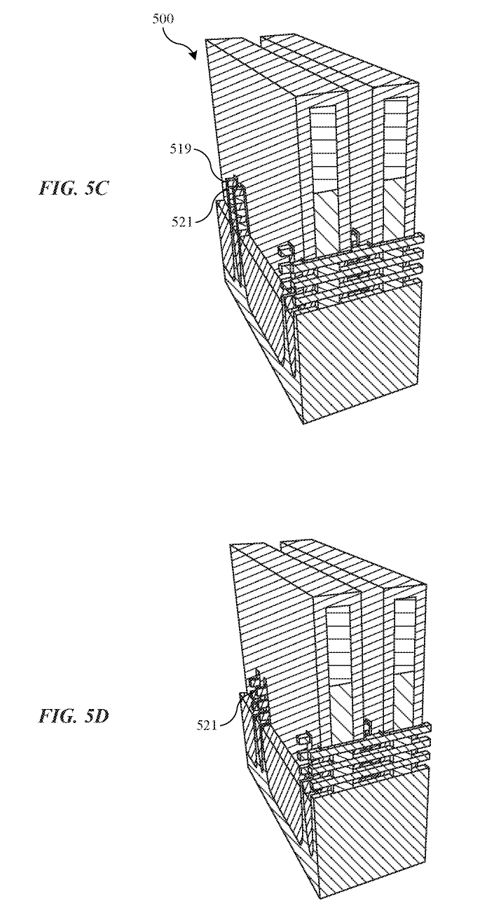

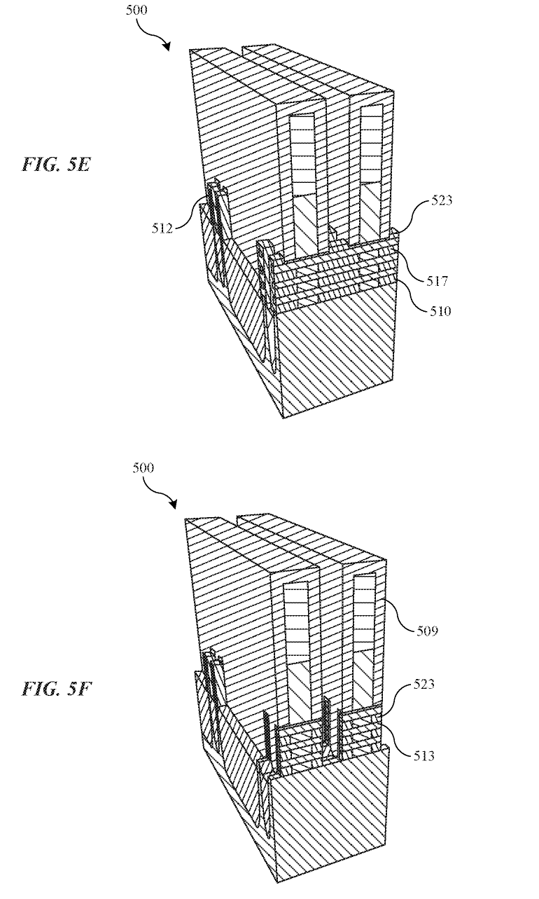

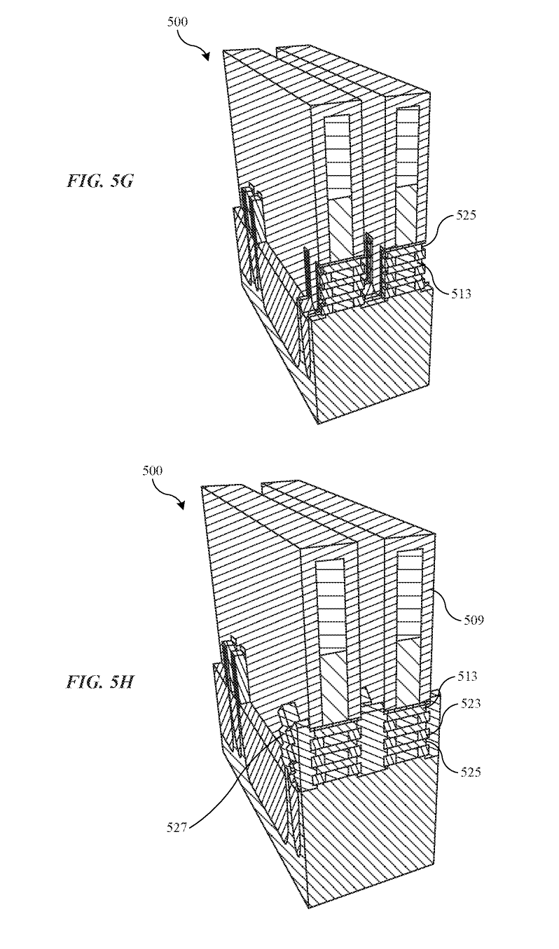

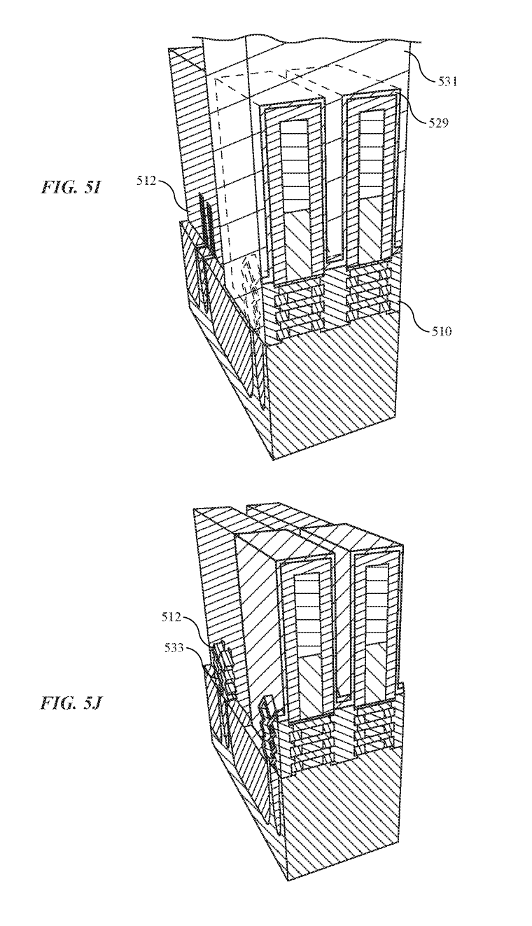

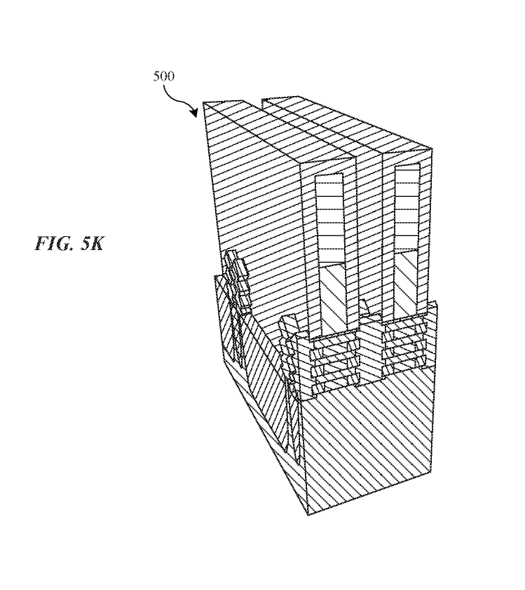

FIG. 4 illustrates an etching method 400, many operations of which may be performed, for example, in the chamber 200 as previously described. Method 400 may include one or more operations prior to the initiation of the method, including front end processing, deposition, etching, polishing, cleaning, or any other operations that may be performed prior to the described operations. The method may include a number of optional operations as denoted in the figure, which may or may not be specifically associated with the method according to the present technology. For example, many of the operations are described in order to provide a broader scope of the structural formation, but are not critical to the technology, or may be performed by alternative methodology as will be discussed further below. Method 400 describes the operations shown schematically in FIG. 5, the illustrations of which will be described in conjunction with the operations of method 400. It is to be understood that FIG. 5 illustrates only partial schematic views, and a substrate may contain any number of transistor sections having aspects as illustrated in the figures.

Method 400 may involve optional operations to develop the semiconductor structure to a particular fabrication operation. As illustrated in FIG. 5A, the semiconductor structure may represent a device after a gate oxide material has been removed in operation 405. As illustrated, structure 500 may include a substrate 501 made of or containing silicon or some other semiconductor substrate material, within which an oxide material 503 or other material for filling trenches has been formed within the substrate 501. Structure 500 may have a number of transistor structures formed overlaying the substrate 501. For example, a dummy gate material 505 may be formed over the substrate 501, which may be removed later in processing to produce a metal gate. Dummy gate 505 may have a cap material 507 formed overlying the dummy gate 505. Additionally, a low-k spacer 509 may be formed about the dummy gate 505. The low-k spacer 509 may be blanketed over the structure and then patterned into the structure illustrated, or low-k spacer 509 may be selectively deposited over the cap material 507 and dummy gate 505.

In some embodiments, the dummy gate may be polysilicon or a silicon-containing material. Cap material 507 may be a dielectric material, and for example, may be silicon nitride. Low-k spacer 509 may also be silicon-nitride, and may be selectively deposited to selectively cover nitride and silicon materials, while not forming or depositing on oxide materials. Although not illustrated for simplicity of understanding, a mask such as a hardmask and/or a photoresist mask may be deposited on part of the structure 500. Although the mask is not illustrated, it will be readily appreciated that a mask may selectively cover part of the structure 500 during certain processing operations. As illustrated, structure 500 includes an N-MOS region 510 and a P-MOS region 512. Several of the operations discussed below may be performed on one side of the structure while the other side remains masked. The masking may then be switched with a removal and re-formation, and then similar operations may be performed on the other structure. These options will be described further below, although it is to be understood that either region may be processed before the other region, and the methods are not limited by the examples described.

Multiple layers of material may be vertically formed over source/drain regions of the substrate 501 for developing nanowires according to the present technology. The layers may include at least one layer of a first silicon-containing material 511, and at least one layer of a second silicon-containing material 513, and may include alternating layers of the materials. As illustrated in FIG. 5A, there are three layers of each portion of each of the source and drain sections, although it will be readily appreciated that there may be less than three, such as two or one layer of each, as well as more than three, such as 4, 5, 6, 7, 10, or more layers of each. As illustrated, layer 513 may be or include the same material as the substrate material 501 in embodiments.

Depending on whether the described operations are included in the N-MOS region 510 or the P-MOS region 512, the first silicon-containing material and the second silicon-containing material may be different depending on the particular nanowire structure being formed. For example, on the N-MOS side of the structure, the nanowires may be formed from silicon, and thus the second silicon-containing material 513 may be or include silicon, while the first silicon-containing material may be, for example, silicon germanium having a first germanium content. However, on the P-MOS side of the structure, the nanowires may be formed from or include silicon germanium, for example, and thus the second silicon-containing material may be silicon germanium having a second germanium content higher than the first, while the first silicon-containing material may be, for example, silicon. These differences will be explained further in conjunction with the figures and description below.

As illustrated, oxide material 515 has been removed from the first silicon-containing material 511 and the second silicon-containing material 513 in the N-MOS region 510 of the semiconductor structure 500. However, oxide material 515 still resides on the P-MOS region 512 of the semiconductor structure 500. As noted above, this may be due to a mask over the P-MOS region 512, although the mask is not illustrated for ease of explanation.

The removal operation 405 may be performed in chamber 200 previously described, which may allow an oxide selective etch to be performed, which may remove the oxide layer 515 from the first silicon-containing material 511 and the second silicon-containing material on both sides of the gate structure. The process may be performed using a dry etch process utilizing a plasma or remote plasma, which may produce plasma effluents of a halogen-containing precursor, such as, for example, a fluorine-containing precursor, or a chlorine-containing precursor. The process may also utilize a hydrogen-containing precursor in embodiments, which may also be included in the remote plasma or may bypass the remote plasma to interact with radical halogen-containing plasma effluents in the processing region.

The process may be performed below about 10 Torr in embodiments, and may be performed below or about 5 Torr in embodiments. The process may also be performed at a temperature below about 100° C. in embodiments, and may be performed below about 50° C. As performed in chamber 200, or a variation on this chamber, or in a different chamber capable of performing similar operations, the process may remove oxide material 515 selective to first silicon-containing material 511, second silicon-containing material 513, and low-k spacer 509. In embodiments, the process may have a selectivity relative to first silicon-containing material and second silicon-containing material greater than or about 100:1, and may have a selectivity greater than or about 200:1, greater than or about 300:1, greater than or about 400:1, or greater than or about 500:1 in embodiments. The process may also have selectivity relative to the low-k spacer greater than 50:1. Because of this selectivity, and because the oxide material 515 may be only a few nanometers in thickness, the first silicon-containing material 511 and the second silicon-containing material 513 may be substantially or essentially maintained during this removal operation. Oxide material 503 may not be as readily maintained, however the dimensions of this material may not be critical, and thus slight removal during removal of oxide material 515 may be acceptable in embodiments.

A lateral etching operation may be performed on the first silicon-containing material in operation 410 as illustrated in FIG. 5B. The lateral etch may be performed isotropically to remove first silicon-containing material from both sides of the gate structure, such as on both sides of dummy gate 505, and may not fully remove the first silicon-containing material. The lateral etch may form a recess 517 defined between the layers of material. For example, recess 517 may be formed between each layer of second silicon-containing material 513, as well as above substrate 501. Recess 517 may also be formed on each side of the gate structure or on each side of a residual portion of first silicon-containing material 511. The recesses may be less than or about 10 nm in length in embodiments, and may be less than or about 8 nm, less than or about 6 nm, less than or about 4 nm, between about 3 nm and about 8 nm, or between about 5 nm and about 7 nm in embodiments. The process may maintain a certain amount of first silicon-containing material that may be located in vertical alignment with the dummy gate material, and may be characterized by dimensions similar to the dummy gate material, and any of the lengths identified above.

The lateral etch may also be performed in chamber 200 similar to operation 405 as discussed above, or may be performed in a variation on that chamber, or in a different chamber capable of performing similar etch operations. The lateral etch process may selectively remove first silicon-containing material 511, which may be silicon germanium, relative to second silicon-containing material 513, which may be silicon. The operation may have a selectivity of the first silicon-containing material relative to the second silicon-containing material greater than or about 50:1 in embodiments, which may allow recessing of the first silicon-containing material while substantially maintaining or essentially maintaining the second silicon-containing material. In some embodiments, the second silicon-containing material may be etched less than or about 1 nm during the lateral etch operation 410, and may be etched less than or about 0.8 nm, less than or about 0.6 nm, less than or about 0.4 nm, less than or about 0.2 nm, less than or about 0.1 nm, or less.

In some embodiments, operations 405 and 410 optionally may be repeated for the P-MOS region 512. This process may involve stripping a photoresist or mask from the P-MOS region 512, and applying a photoresist or mask to the N-MOS region 510. As illustrated in FIG. 5C, the gate oxide has been removed exposing a first silicon-containing material 519 and a second silicon-containing material 521. The gate oxide removal may be performed as described above. The P-MOS region may include opposite materials from the N-MOS region as previously described, and thus the first silicon-containing material 519 may be or include silicon, and the second silicon-containing material 521 may be or include silicon germanium, for example. Turning to FIG. 5D is shown structure 500 after operation 410 is performed in the P-MOS region to laterally etch the first silicon-containing material, which may be silicon, from the second silicon-containing material 521, which may be the nanowire structures for the P-MOS region.

Method 400 may continue to form a spacer material in operation 415. As illustrated in FIG. 5E, spacer material 523 may be formed in both N-MOS region 510 and P-MOS region 512. Spacer material 523 may be formed or deposited in various ways. For example, spacer material 523 may be selectively deposited about the first silicon-containing materials and/or the second silicon-containing materials, or may be formed over the entire structure 500, and then selectively removed from the oxide and nitride regions. Spacer material 523 may be formed about the silicon-containing materials, as well as within the recesses 517 previously formed. The spacer material 523 may be layered between regions of second silicon-containing material and may completely fill recesses 517 to contact remaining portions of first silicon-containing material defined between layers of the second silicon-containing material. Spacer material 523 may be a silicon-containing material in embodiments, and may be or include silicon nitride, silicon carbide, or silicon oxycarbide.

Additional masking may be performed in operation 420 over the P-MOS region 512 before additional processing continues in the N-MOS region 510. Again, as previously stated, either region may be processed first or second, and the exemplary process stated illustrating one scheme is not intended to limit the opposite region being first processed. An anisotropic etch process may then be performed at operation 425. The process may be performed in the unmasked region to remove edge regions of the spacer 523 material and nanowires, which may be the second silicon-containing materials 513. As illustrated in FIG. 5F, a selective etch may be performed to vertically recess portions of the spacer and second silicon-containing material located beyond the exterior of liner 509. The anisotropic etch may remove the material exposed on both sides of the gate regions, while maintaining material that is vertically in line with the gate structure.

An optional lateral push of the nanowires, or second silicon-containing material 513 may be performed in operation 430. As illustrated in FIG. 5G, a selective etch process may be performed in chamber 200 similar to operation 405 previously described. The process may selectively remove regions of the second silicon-containing material 513 from each side of the gate structure. The etch may be performed to a depth of less than 5 nm laterally, and may be performed to produce a recess 525 of less than or about 4 nm, less than or about 3 nm, less than or about 2 nm, less than or about 1 nm, or less in embodiments. By performing the lateral recess, when the contact material is formed, there may be additional strength in the channel, which may be reinforced by the additional contact material within the recess.

A contact may be formed in operation 435, which in the N-MOS region may be silicon phosphide, for example. As illustrated in FIG. 5H, contact material 527 may be formed via epitaxial growth, or some other deposition or formation process. Contact material 527 may be formed between and on both sides of the gate structure to contact each portion of spacer material 523 and second silicon-containing material 513. Contact material 527 may fill recesses 525 formed in the lateral etch of operation 430 in order to extend the contact material into a region vertically in line with liner 509.

After contact formation, the mask material over the P-MOS region may be removed, and then applied to the N-MOS region. The contact formation process may then be repeated in the P-MOS region. As illustrated in FIG. 5I, a hard mask material 529 and a photoresist material 531 is illustrated over N-MOS region 510 in an operation 420, while the P-MOS region is being processed. An anisotropic etch may be performed in P-MOS region 512 in operation 425. The anisotropic etch may be as previously described, and may vertically recess the second silicon-containing material and the spacer material from the exterior of the gate structure. A lateral push of the second silicon-containing material may be performed in the P-MOS region in optional operation 430 as previously described.

A contact material may be grown or formed in the P-MOS region 512 in operation 430, similar to the operation previously described in relation to the N-MOS structure. As illustrated in FIG. 5J, contact material 533 may be formed in P-MOS region 512 at the source and drain portions of the structure. The contact material 533 may be or include a silicon-containing material, and may be silicon germanium in embodiments. Although the figure does not show the photoresist previously illustrated, it may still be positioned in the N-MOS region, but has not been included in the figure. Turning to FIG. 5K, a structure 500 is illustrated that includes formed contact materials over spacers formed according to the present technology. The structure allows spacers to be formed on both sides of the gate earlier in the fabrication process before dummy gate removal. By increasing the lateral access to both sides of the gate structure, improved spacers may be formed that have more uniform structure and size compared to conventional structures that were produced after dummy gate removal from one side of the gate structure.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a layer” includes a plurality of such layers, and reference to “the precursor” includes reference to one or more precursors and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A method of forming a sidewall spacer, the method comprising:
laterally etching a first silicon-containing material relative to a second silicon-containing material, wherein the first silicon-containing material and the second silicon-containing material are disposed vertically from one another, and wherein the first silicon-containing material is positioned vertically between two regions of the second silicon-containing material;
forming a spacer within a recess defined by the lateral etching between the two regions of the second silicon-containing material; and
forming a contact material adjacent to and contacting both the second silicon-containing material and the spacer.

2. The method of forming a sidewall spacer of claim 1, wherein the first silicon-containing material is partially recessed from two sides of a gate formation.

3. The method of forming a sidewall spacer of claim 2, wherein the contact is formed on each of the two sides of the gate formation.

4. The method of forming a sidewall spacer of claim 1, wherein at least one region of the second silicon-containing material comprises a silicon nanowire.

5. The method of forming a sidewall spacer of claim 1, wherein the first silicon-containing material and the second silicon-containing material are selected from the group consisting of silicon, silicon germanium, and silicon phosphide.

6. The method of forming a sidewall spacer of claim 1, wherein the spacer comprises silicon nitride, silicon carbide, or silicon oxycarbide.

7. The method of forming a sidewall spacer of claim 1, further comprising laterally etching the second silicon-containing material prior to forming the contact material, wherein the contact material is formed within a recess defined by the lateral etching of the second silicon-containing material.

8. The method of forming a sidewall spacer of claim 1, wherein the first silicon-containing material and the second silicon containing material are positioned between a dummy gate material and a semiconductor substrate.

9. The method of forming a sidewall spacer of claim 1, wherein the first silicon-containing material is etched laterally less than 10 nm.

10. The method of forming a sidewall spacer of claim 1, wherein the first silicon-containing material comprises silicon germanium, and wherein the contact material comprises silicon phosphide.

11. The method of forming a sidewall spacer of claim 1, wherein the first silicon-containing material comprises silicon, and wherein the contact material comprises silicon germanium.

12. A semiconductor structure, the structure comprising:
a substrate;
a first silicon-containing material overlying the substrate;
a second silicon-containing material overlying the first silicon-containing material;
a recess defined on each of two opposite sides of the first silicon-containing material, the recess defined at least partially from above by the second silicon-containing material;
a spacer positioned within each recess adjacent the first silicon-containing material; and
a dummy gate material overlying the second silicon-containing material.

13. The semiconductor structure of claim 12, wherein the dummy gate material comprises polysilicon.

14. The semiconductor structure of claim 12, further comprising a contact material adjacent the second silicon-containing material and the spacer.

15. The semiconductor structure of claim 14, wherein the first silicon-containing material comprises silicon germanium, and wherein the contact material comprises silicon phosphide.

16. The semiconductor structure of claim 14, wherein the first silicon-containing material comprises silicon, and wherein the contact material comprises silicon germanium.

17. A method of forming a semiconductor structure, the method comprising:
partially etching a first silicon-containing material relative to a second silicon-containing material, wherein the first silicon-containing material and the second silicon-containing material are disposed vertically from one another, and wherein the partial etching is performed laterally;
forming a spacer within a recess defined by the lateral etching and at least partially defined by the second silicon-containing material;
anisotropically etching the spacer material and the second silicon-containing material vertically towards a substrate;
partially etching the second silicon-containing material laterally along the spacer; and
forming a contact material adjacent to and contacting both the second silicon-containing material and the spacer.

18. The method of forming a semiconductor structure of claim 17, wherein the first silicon-containing material comprises silicon germanium, and wherein the contact material comprises silicon phosphide.

19. The method of forming a semiconductor structure of claim 17, wherein the first silicon-containing material comprises silicon, and wherein the contact material comprises silicon germanium.

20. The method of forming a semiconductor structure of claim 17, wherein the first silicon-containing material and the second silicon containing material are positioned below a dummy gate material on the substrate, wherein the dummy gate comprises polysilicon, and wherein at least one of the first silicon-containing material and the second silicon-containing material comprises a nanowire.
